(19) United States
(12) Patent Application Publication
(10) Pub. No.: US 2026/0160795 A1
(43) Pub. Date: Jun. 11, 2026

(54) UNIVERSAL SERIAL BUS TYPE-C CONNECTER CHIP, TEST SYSTEM AND CALIBRATION METHOD OF UNIVERSAL SERIAL BUS TYPE-C CONNECTER CHIP

(71) Applicant: Realtek Semiconductor Corp., HsinChu (TW)

(72) Inventors: Xinchun Xia, Suzhou City (CN); Teng Liu, Suzhou City (CN)

(73) Assignee: Realtek Semiconductor Corp., HsinChu (TW)

(21) Appl. No.: 19/399,550

(22) Filed: Nov. 24, 2025

(30) Foreign Application Priority Data
Dec. 10, 2024 (CN) 202411812901.0

(51) Int. Cl. G01R 31/28; G01R 19/165; G01R 19/25; G01R 35/00

(52) U.S. Cl. CPC G01R 31/2813; G01R 19/16576; G01R 19/2503; G01R 31/2806; G01R 35/005

(57) ABSTRACT

A universal serial bus type-C (USB-C) connecter chip, a test system and a calibration method of the USB-C connecter chip are provided. The USB-C connecter chip includes the determination circuit and a calibration control circuit, wherein the determination circuit is configured to determine whether a detection voltage on a detection pin of the USB-C connecter chip reaches a threshold voltage. In a first calibration phase, the calibration control circuit sets the detection voltage to a first direct current (DC) level to obtain a first calibration value of the threshold voltage. In a second calibration phase, the calibration control circuit sets the detection voltage to a second DC level to obtain a second calibration value of the threshold voltage. More particularly, the calibration control circuit determines a final calibration value of the threshold voltage according to the first calibration value and the second calibration value.

### BACKGROUND OF THE INVENTION

### 1. Field of the Invention

The present invention is related to universal serial bus type-C (USB-C) connectors, and more particularly, to a USB-C connecter chip, a test system and a calibration method of the USB-C connecter chip.

### 2. Description of the Prior Art

A universal serial bus type-C (USB-C) connector can determine a connecting orientation (e.g. flipped connection or un-flipped connection) by detecting a voltage level of a configuration channel (CC) pin and a voltage bus (VBUS) pin, to establish a USB-C connection for implementing functions such as charging and data transfer. Different voltage level detection results correspond to different application scenarios. In particular, USB-C has numerous application scenarios. For example, different voltages connected to the CC pin represent different levels of power supply capability of a source connected by the USB-C connector, and different charging wattages of USB power delivery (USB-PD) also correspond to different voltages of the VBUS pin. Thus, a large number of comparators and corresponding threshold voltages are required to implement the voltage level detection mentioned above. Especially, corresponding calibration flows are required during a chip mass production phase, in order to ensure that the voltage level detection mentioned above meets the accuracy requirement.

Some related arts can utilize additional high-precision circuits or automatic calibration circuits to accurately monitor the threshold voltage involved in the above detection to ensure detection accuracy. During a chip manufacturing phase, system designers can impose stringent requirements on the manufacturing process of the chip to ensure that differences in characteristics at different locations on the wafer fall in tolerable ranges. However, the approaches mentioned above significantly increase design complexity and cost. Thus, there is a need for a novel architecture and an associated method, which can calibrate the voltage detection of the USB-C connector with little or no side effects.

### SUMMARY OF THE INVENTION

An objective of the present invention is to provide a universal serial bus type-C (USB-C) connector chip, a test system and a calibration method of the USB-C connecter chip, in order to solve the problem of the related art without introducing any side effect or in a way that is less likely to introduce side effects.

At least one embodiment of the present invention provides a universal serial bus type-C (USB-C) connecter chip. The USB-C connector chip comprises a determination circuit and a calibration control circuit, where the calibration control circuit is coupled to the determination circuit. The determination circuit is configured to determine whether a detection voltage on a first input terminal of the determination circuit reaches a threshold voltage on a second input terminal of the determination circuit, in order to generate a determination signal, where the first input terminal is coupled to a detection pin of the USB-C connector chip. The calibration control circuit is configured to calibrate the threshold voltage transmitted to the second input terminal. In a first calibration phase, the calibration control circuit sets the detection voltage to a first direct current (DC) level, sets the threshold voltage to multiple candidate calibration levels to obtain multiple first determination results of the determination signal, and selects a first calibration level from the multiple candidate calibration levels according to the multiple first determination results. In a second calibration phase, the calibration control circuit sets the detection voltage to a second DC level, sets the threshold voltage to the multiple candidate calibration levels to obtain multiple second determination results of the determination signal, and selects a second calibration level from the multiple candidate calibration levels according to the multiple second determination results. In addition, the calibration control circuit determines a final calibration level of the threshold voltage according to the first calibration level and the second calibration level.

At least one embodiment of the present invention provides a test system. The test system comprises a test circuit, a USB-C connector chip and a digital-to-analog converter (DAC), where the USB-C connector chip is coupled to the test circuit, and the DAC is coupled to the USB-C connector chip. The USB-C connector chip comprises a determination circuit and a calibration control circuit, where the calibration control circuit is coupled to the determination circuit. The test circuit is configured to transmit a test command. The determination circuit is configured to determine whether a detection voltage on a first input terminal of the determination circuit reaches a threshold voltage on a second input terminal of the determination circuit, in order to generate a determination signal, where the first input terminal is coupled to a detection pin of the USB-C connector chip. The calibration control circuit is configured to calibrate the threshold voltage transmitted to the second input terminal according to the test command. The DAC is configured to output the detection voltage to the detection pin of the USB-C connector chip. In a first calibration phase, the calibration control circuit controls the DAC to output the detection voltage having a first DC level, sets the threshold voltage to multiple candidate calibration levels to obtain multiple first determination results of the determination signal, and selects a first calibration level from the multiple candidate calibration levels according to the multiple first determination results. In a second calibration phase, the calibration control circuit controls the DAC to output the detection voltage having a second DC level, sets the threshold voltage to the multiple candidate calibration levels to obtain multiple second determination results of the determination signal, and selects a second calibration level from the multiple candidate calibration levels according to the multiple second determination results. In addition, the calibration control circuit determines a final calibration level of the threshold voltage according to the first calibration level and the second calibration level.

At least one embodiment of the present invention provides a calibration method of a USB-C connecter chip. The calibration method comprises: in a first calibration phase, setting a detection voltage on a first input terminal of a determination circuit to a first DC level; in the first calibration phase, setting a threshold voltage on a second input terminal of the determination circuit to multiple candidate calibration levels; in the first calibration phase, utilizing the determination circuit to determine whether the multiple candidate calibration levels reach the first DC level, in order to generate multiple first determination result of a determination signal; in the first calibration phase, selecting a first calibration level from the multiple candidate calibration levels according to the multiple first determination results; in a second calibration phase, setting the detection voltage on the first input terminal of the determination circuit to a second DC level; in the second calibration phase, setting the threshold voltage on the second input terminal of the determination circuit to the multiple candidate calibration levels; in the second calibration phase, utilizing the determination circuit to determine whether the multiple candidate calibration levels reach the second DC level, in order to generate multiple second determination result of the determination signal; in the second calibration phase, selecting a second calibration level from the multiple candidate calibration levels according to the multiple second determination results; and determining a final calibration level according to the first calibration level and the second calibration level.

The USB-C connector chip, the test system and the calibration method provided by the embodiments of the present invention obtain two calibration values under two levels of the detection voltage, and compare these two calibration values to determine which one of them is closer to a target value, thereby improving calibration precision. In addition, the embodiments of the present invention will not greatly increase additional costs. Thus, the present invention can complete the calibration of the threshold voltage without introducing any side effect or in a way that is less likely to introduce side effects.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram illustrating a source device and a sink device connected to each other via a cable according to an embodiment of the present invention.

FIG. 2 is a diagram illustrating a test system for testing a universal serial bus type-C (USB-C) connecter chip according to an embodiment of the present invention.

FIG. 3 is a diagram illustrating calibration gears for determining a threshold voltage according to an embodiment of the present invention.

FIG. 4 is a diagram illustrating a working flow of a calibration method of a USB-C connecter chip according to an embodiment of the present invention.

FIG. 5 is an example of the calibration method shown in FIG. 4 according to an embodiment of the present invention.

### DETAILED DESCRIPTION

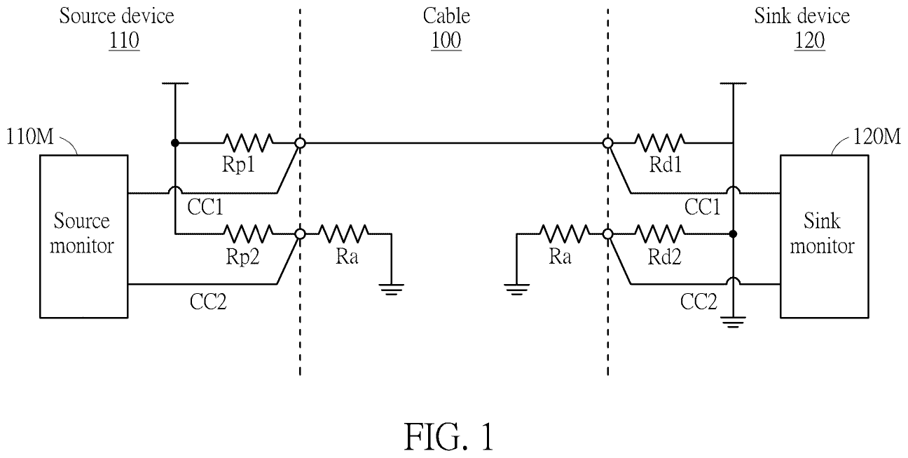

FIG. 1 is a diagram illustrating a source device 110 and a sink device 120 connected to each other via a cable 100 according to an embodiment of the present invention, where the cable 100 may be a universal serial bus (USB) type-C (USB-C) cable, and each of the source device 110 and the sink device 120 may be equipped with a USB-C connector, to allow the source device 110 and the sink device 120 to be connected to each other via the USB-C cable. Configuration channel (CC) pins CC1 and CC2 of the source device 110 are coupled to resistors Rp1 and Rp2, respectively, and the CC pins CC1 and CC2 of the sink device 120 are coupled to resistors Rd1 and Rd2, respectively. When the source device 110 and the sink device 120 are connected to each other via the cable 100, one of the CC pins CC1 and CC2 of the source device 110 may be connected to one of the CC pins CC1 and CC2 of the sink device 120 via the cable 100, and the other one is coupled to a resistor Ra of the cable 100. Similarly, one of the CC pins CC1 and CC2 of the sink device 120 may be connected to one of the CC pins CC1 and CC2 of the source device 110 via the cable 100, and the other one is coupled to the resistor Ra of the cable 100. Thus, different voltage division results may represent different connection states, where a source monitor 110M within the source device 110 may determine a present connection state (e.g. whether it is connected, flipped/un-flipped connection, functions supported by the sink device 120) by detecting voltage levels of the CC pins CC1 and CC2 of the source device, and a sink monitor 120M within the sink device 120 may determine a present connection state (e.g. whether it is connected, flipped/un-flipped connection, functions supported by the source device 110) by detecting voltage levels of the CC pins CC1 and CC2 of the sink device 120. As different connection states and usage scenarios may correspond to different voltage levels of each of the CC pins CC1 and CC2, each of the source monitor 110M and the sink monitor 120M needs to comprise multiple determination circuits (e.g. comparators), and these determination circuits may perform determination on the voltage level of each of the CC pins CC1 and CC2 based on different threshold voltages (e.g. 0.2V, 0.4V, 0.66V, 0.8V, 1.23V, 1.6V and 2.6V), respectively. In addition, a voltage bus (VBUS) pin of each of the source device 110 and the sink device 120 may have different voltage levels to support different power supply modes. Thus, each of the source monitor 110M and the sink monitor 120M is also equipped with corresponding determination circuits to determine whether the voltage level of the VBUS pin reaches a specific level. After the source device 110 and the sink device complete the USB-C connection, the voltage levels of the CC pins CC1 or CC2 and the VBUS pin still need to be continuously monitored. For example, the voltage level mentioned above may be continuously monitored to implement signal communication of USB power delivery (USB-PD) on the CC pins CC1 or CC2 of the source device 110 and the sink device 120, to allow the VBUS pin perform the power delivery with higher power. In another example, the voltage level mentioned above may be continuously monitored to implement disconnection monitoring, to remove the voltage on the VBUS pin in response to the disconnection event in time.

As mentioned above, each of the source monitor 110M and the sink monitor 120M needs to be equipped with a great number of determination circuits for determination of multiple connection states and usage scenarios. Precision requirement of the threshold voltage corresponding to each determination circuit is quite high, and corresponding calibration mechanisms for calibrating these threshold voltages are therefore needed.

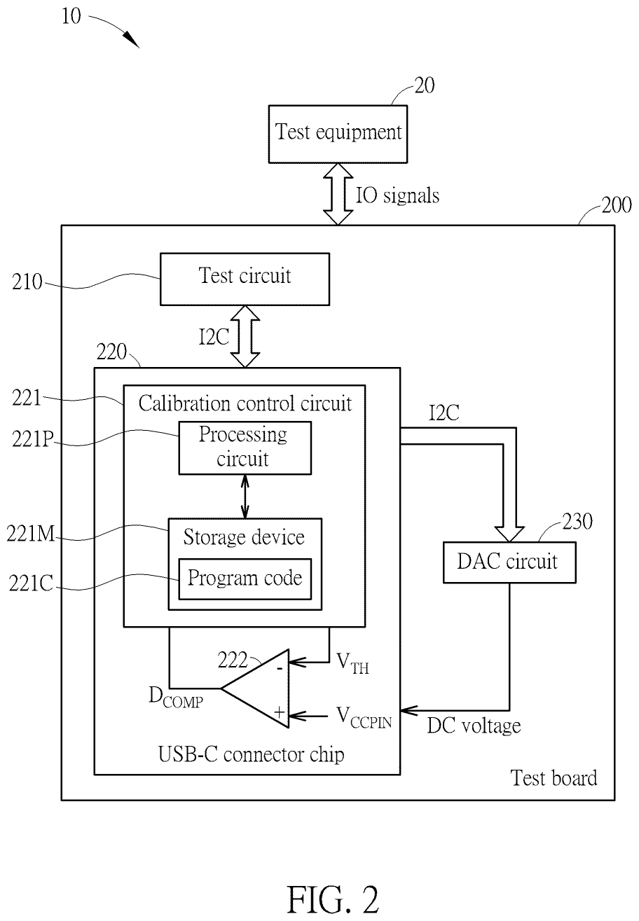

FIG. 2 is a diagram illustrating a test system 10 for testing a USB-C connecter chip 220 according to an embodiment of the present invention, where the test system 10 may comprise a test equipment 20, a test circuit 210, the USB-C connector chip 220 and a digital-to-analog converter (DAC) circuit 230 (e.g. a high precision DAC circuit installed at outside of the USB-C connector chip 220). As shown in FIG. 2, the USB-C connector chip 220 coupled to the test circuit 210 via an inter-integrated circuit (I2C) interface, and the DAC circuit 230 is coupled to the USB-C connector chip 220 via an I2C interface. In this embodiment, the test circuit 210, the USB-C connector chip 220 and the DAC circuit 230 may be installed on a test board 200, and the test equipment 20 may transmit input/output (IO) signals to components (e.g, the test circuit 210) on the test board 200 via an IO interface of the test board 200. In one embodiment, the test circuit 210 may be implemented with a field programmable gate array (FPGA), but the present invention is not limited thereto.

For example, the test equipment 20 may control a robotic arm to put a device under test (DUT) such as the USB-C connector chip 220 on the test board 200, and control the test circuit 210 to start executing the test flow with the IO signals, where the test circuit 210 may stepwise execute multiple test/calibration operations, and these test/calibration operations may comprise calibration of the determination circuits. As shown in FIG. 2, the USB-C connector chip 220 may comprise a determination circuit 222 and a calibration control circuit 221, where the calibration control circuit 221 is coupled to the determination circuit 222. In this embodiment, the determination circuit 222 may be implemented with a comparator. In this embodiment, the calibration control circuit 221 may comprise a processing circuit 221P and a storage device 221M, where the processing circuit 221P may execute operations of the calibration control circuit 221 (e.g. calibration of the determination circuit 222) according to a program code 221C (e.g. firmware) stored in the storage device 221M. In this embodiment, the test circuit 210 is configured to transmit a test command (e.g. a test command corresponding to calibration of the determination circuit 222. In particular, the determination circuit 222 is configured to determine whether a detection voltage V_{CCPIN} on a first input terminal (e.g. a terminal labeled “+” thereon) of the determination circuit 222 reaches a threshold voltage V_{TH} on a second input terminal (e.g. a terminal labeled “−” thereon) of the determination circuit 222, in order to generate a determination signal DCOMP, where the first input terminal of the determination circuit 222 is coupled to a detection pin (e.g, the CC pin CC1 or CC2, or the VBUS pin) of the USB-C connector chip 220, and the calibration control circuit 221 is configured to calibrate the threshold voltage V_{TH} transmitted to the second input terminal of the determination circuit 222 according to the test command. In addition, the DAC circuit 230 is configured to output a direct current (DC) voltage such as a detection voltage V_{CCPIN} to the detection pin of the USB-C connector chip 220.

In a first calibration phase, the calibration control circuit 221 may set the detection voltage V_{CCPIN} to a first DC level (e.g. controlling the DAC circuit 230 to output the detection voltage V_{CCPIN} having the first DC level), and sequentially set the threshold voltage V_{TH} to multiple candidate calibration level to obtain multiple determination results of the determination signal DCOMP, where the calibration control circuit 221 may select a first calibration level from the multiple candidate calibration levels according to the multiple first determination results. In a second calibration phase, the calibration control circuit 221 may set the detection voltage V_{CCPIN} to a second DC level (e.g. controlling the DAC circuit 230 to output the detection voltage V_{CCPIN} having the second DC level), and sequentially set the threshold voltage V_{TH} to the multiple candidate calibration levels to obtain multiple second determination results of the determination signal DCOMP, where the calibration control circuit 221 may second a second calibration level from the multiple candidate calibration levels according to the multiple second determination results. More particularly, the calibration control circuit 221 may determine a final calibration level according to the first calibration level and the second calibration level.

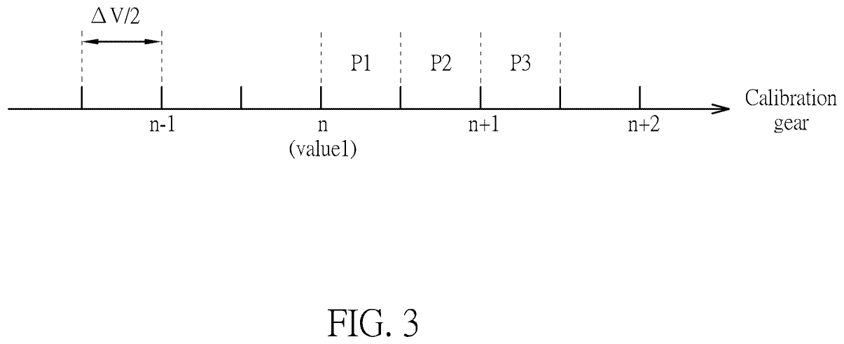

FIG. 3 is a diagram illustrating calibration gears for determining the threshold voltage V_{TH} according to an embodiment of the present invention, where calibration gears n−1, n, n+1 and n+2 may represent four consecutive calibration gears of the threshold voltage V_{TH}, and these four calibration gears may correspond to arbitrary four consecutive calibration levels among the multiple candidate calibration levels, respectively. In this embodiment, the multiple candidate calibration levels are spaced with a fixed voltage difference ΔV, and a unit scale on a horizontal axis of FIG. 3 represents half the voltage difference ΔV (i.e. ΔV/2). In this embodiment, the calibration levels corresponding to the calibration gears n−1, n, n+1 and n+2 are arranged from low to high. It should be noted that when a voltage level of the first input terminal of the determination circuit 222 is less than a voltage level of the second input terminal of the determination circuit 222 (e.g. V_{CCPIN}<V_{TH}), the determination signal DCOMP output from the determination circuit 222 may has a logic value “0”. When the voltage level of the first input terminal of the determination circuit 222 is greater than the voltage level of the second input terminal of the determination circuit 222 (e.g. V_{CCPIN}>V_{TH}), the determination signal DCOMP output from the determination circuit 222 may has a logic value “1”. In this embodiment, it is assumed that the calibration control circuit 221 sequentially sets the calibration gear to n−1, n, n+1 and n+2 to make the threshold voltage V_{TH} gradually increase. If the threshold voltage V_{TH} is switched from a certain calibration gear (e.g. the calibration gear n) to a next calibration gear (e.g, the calibration gear n+1) and therefore makes the determination signal DCOMP be changed from the logic value “1” to the logic value “0”, the calibration control circuit 221 may record the calibration gear n to be the selected calibration gear. Thus, when the threshold voltage V_{TH} is changed from the first calibration level (e.g, the candidate calibration level corresponding to a calibration gear value1 selected in the first calibration phase) to a next candidate calibration level of the first calibration level, the determination signal DCOMP is changed from the logic value “1” to the logic value “0”. Similarly, when the threshold voltage V_{TH} is changed from the second calibration level (e.g, the candidate calibration level corresponding to a calibration gear value2 selected in the second calibration phase) to a next candidate calibration level of the second calibration level, the determination signal DCOMP is changed from the logic value “1” to the logic value “0”.

When the calibration control circuit 221 selects the candidate calibration level corresponding to the calibration gear n to be the first calibration level in the first calibration phase, it means that a target voltage (i.e, the detection voltage V_{CCPIN} output from the DAC circuit 230 in the first calibration phase) falls in an interval between the candidate calibration level corresponding to the calibration gear n and the candidate calibration level corresponding to the calibration gear n+1 (i.e. falling in an interval P1 or P2). In the second calibration phase, the detection voltage V_{CCPIN} output from the DAC circuit 230 may be increased by ΔV/2, which means that a voltage difference between the first DC level and the second DC level is equal to a half of the voltage difference between any two consecutive candidate calibration levels among the multiple candidate calibration levels (i.e. ΔV/2). If the candidate calibration level corresponding to the calibration gear n is closer to the target voltage than the candidate calibration level corresponding to the calibration gear n+1, it means that the target voltage falls in the interval P1, and the second DC level may fall in the interval P2, making the calibration gear n be the calibration gear value2 selected in the second calibration phase. If the candidate calibration level corresponding to the calibration gear n+1 is closer to the target voltage than the candidate calibration level corresponding to the calibration gear n, it means that the target voltage falls in the interval P2, and the second DC level may fall in the interval P3, making the calibration gear n+1 be the calibration gear value2 selected in the second calibration phase. Thus, when the first calibration level is equal to the second calibration level (e.g, the calibration gear value1 is equal to the calibration gear value2), the calibration control circuit 221 may select the first calibration level (e.g. selecting the calibration level corresponding to the calibration gear value1) to be the final calibration level. When the second DC level is greater than the first DC level (e.g, the second DC level is equal to the first DC level plus ΔV/2) and the second calibration level is greater than the first calibration level (e.g, the calibration level corresponding to the calibration gear value2 is greater than the calibration level corresponding to the calibration gear value1), the calibration control circuit 221 may select the second calibration level (e.g. selecting the calibration level corresponding to the calibration gear value2) to be the final calibration level.

In some embodiments, the calibration control circuit 221 may gradually switch the calibration gear from high calibration gears to low calibration gears (e.g. sequentially setting the calibration gear to be n+2, n+1, n and n−1 to make the threshold voltage V_{TH} gradually decrease). If the threshold voltage V_{TH} is switched from a certain calibration gear (e.g, the calibration gear n) to a next calibration gear (e.g, the calibration gear n−1) and therefore makes the determination signal DCOMP be changed from the logic value “0” to the logic value “1”, the calibration control circuit 221 may record the calibration gear n to be the selected calibration gear. Under this condition, the calibration control circuit 221 may control the DAC circuit 230 to set the second DC level to be the first DC level minus ΔV/2. Thus, when the first calibration level is equal to the second calibration level (e.g, the calibration gear value1 is equal to the calibration gear value2), the calibration control circuit 221 may select the first calibration level (e.g. selecting the calibration level corresponding to the calibration gear value1) to be the final calibration level. When the second DC level is less than the first DC level (e.g, the second DC level is equal to the first DC level minus ΔV/2) and the second calibration level is less than the first calibration level (e.g, the calibration level corresponding to the calibration gear value2 is less than the calibration level corresponding to the calibration gear value1), the calibration control circuit 221 may select the second calibration level (e.g. selecting the calibration level corresponding to the calibration gear value2) to be the final calibration level.

TABLE 1

| Calibration gear | Calibration level |
|---|---|
| #0 | 1.105 V |
| #1 | 1.125 V |
| #2 | 1.145 V |
| #3 | 1.165 V |
| #4 | 1.185 V |
| #5 | 1.205 V |
| #6 | 1.225 V |
| #7 | 1.245 V |
| #8 | 1.265 V |
| #9 | 1.285 V |
| #10 | 1.305 V |
| #11 | 1.325 V |
| #12 | 1.345 V |
| #13 | 1.365 V |
| #14 | 1.385 V |
| #15 | 1.405 V |

Table 1 is an example of the multiple candidate calibration levels of the threshold voltage V_{TH}, where the threshold voltage V_{TH} may have multiple calibration gears such as #0, #1, #2, #3, #4, #5, #6, #7, #8, #9, #10, #11, #12, #13, #14 and #15, and these calibration gears may represent different values stored in a register of the determination circuit 222, where the calibration control circuit 221 may output corresponding calibration levels according to the values stored in the register of the determination circuit 222, and more particularly, the voltage difference between calibration levels of any two consecutive calibration gears is fixed at 20 mV. Assume that the determination circuit 222 is a comparator which takes 1.23V as its threshold. However, the threshold voltage V_{TH} received by the determination circuit 222 on different chips may be different (e.g, the same calibration gear correspond to different calibration levels on different chips) due to factors such as chip sizes, doping concentration deviation and process variation. Thus, a calibration mechanism is required in order to find the calibration gear which is the closest to 1.23V among these calibration gears.

In this embodiment, the calibration control circuit 221 may control the DAC circuit 230 to output 1.23V and control the threshold voltage V_{TH} to be gradually switched from low calibration gears to high calibration gears (e.g. gradually switched from the calibration gear #0 to the calibration gear #15), making the level of the threshold voltage V_{TH} be gradually increased. In the first calibration phase, the calibration control circuit 221 may control the DAC circuit 230 to output the first DC level such as 1.23V, and the threshold voltage V_{TH} may be gradually increased, starting from 1.105V, where when the threshold voltage V_{TH} is switched from the calibration gear #6 (V_{TH}=1.225V) to the calibration gear #7 (V_{TH}=1.245V), the determination signal DCOMP may be changed from the logic value “1” (1.23V>1.225V) to the logic value “0” (1.23V<1.245V), and the calibration control circuit 221 may record the calibration level corresponding to the calibration gear #6 to be the first calibration level. In the second calibration phase, the calibration control circuit 221 may control the DAC circuit 230 to output the second DC level such as 1.24V (V_{CCPIN}=1.23V+ (20 mV)/2), and the threshold voltage V_{TH} may be gradually increased, starting from 1.105V, where when the threshold voltage V_{TH} is switched from the calibration gear #6 (V_{TH}=1.225V) to the calibration gear #7 (V_{TH}=1.245V), the determination signal DCOMP may be changed from the logic value “1” (1.24V>1.225V) to the logic value “0” (1.24V<1.245V), and the calibration control circuit 221 may record the calibration level corresponding to the calibration gear #6 to be the second calibration level.

As mentioned above, the voltage difference between the first DC level (e.g. 1.23V) and the second DC level (e.g. 1.24V) is equal to half the voltage difference between any two consecutive candidate calibration levels among the multiple candidate calibration levels (e.g. 10 mV). Thus, when the first calibration level is equal to the second calibration level, it means that the first calibration level is closer to the target voltage (e.g. 1.23V) than the second calibration level, and the calibration control circuit 221 may select the first calibration level to be the final calibration level, where the calibration gear #6 may be written into a one-time programmable storage device for being directly read in subsequent operations.

Deduced by analogy, assume that the determination circuit 222 is a comparator which takes 1.24V as its threshold, the calibration control circuit 221 may record the calibration level corresponding to the calibration gear #6 to be the first calibration level in the first calibration phase (at which the DAC circuit 230 outputs 1.24V), and record the calibration level corresponding to the calibration gear #7 to be the second calibration level in the second calibration phase (at which the DAC circuit 230 outputs 1.25V). Under this condition, as the second DC level (e.g. 1.25V) is greater than the first DC level (e.g. 1.24), when the second calibration level is greater than the first calibration level, it means that the second calibration level is closer to the target voltage (i.e. the first DC level) than the first calibration level, and the calibration control circuit 221 may select the second calibration level to be the final calibration level. In this embodiment, the calibration levels corresponding to the multiple calibration gears such as #0 to #15 shown in Table 1 are theoretical values. In practice, actual calibration levels corresponding to the calibration gears of each chip may has deviations in comparison with the theoretical values, and thus different chips may have different calibration levels. Under some conditions, when a specific calibration gear (e.g. #0 or #15) of a certain chip exceeds an allowable range, this chip may be discarded. For example, when the calibration level corresponding to the calibration gear #0 of a certain chip is greater than 1.24V, this chip may be directly discarded. In another example, when the calibration level corresponding to the calibration gear #0 of this chip is less than 1.24V, this chip may be directly discarded.

In some embodiments, the calibration control circuit 221 may control the threshold voltage V_{TH} to be gradually switched from low calibration gears to high calibration gears (e.g. gradually switched from the calibration gear #0 to the calibration gear #15) to make the level of the threshold voltage V_{TH} be gradually increased, and set the second DC level to be the first DC level minus 10 mV. Associated details under such settings may be deduced by analogy according to descriptions of the above paragraphs, and are omitted here for brevity.

In some embodiments, the detection pin of the USB-C connector chip 220 is a CC pin, and multiple different levels of the detection voltage on the CC pin correspond to multiple different connection states of the USB-C connector chip 220 (e.g. whether it is connected, flipped/un-flipped connection, functions supported by the connected device), respectively. In some embodiments, the detection pin of the USB-C connector chip 220 is a VBUS pin, and multiple different levels of the detection voltage on the VBUS pin correspond to multiple power supply states of the USB-C connector chip 220 (e.g. different levels of a supply voltage), respectively.

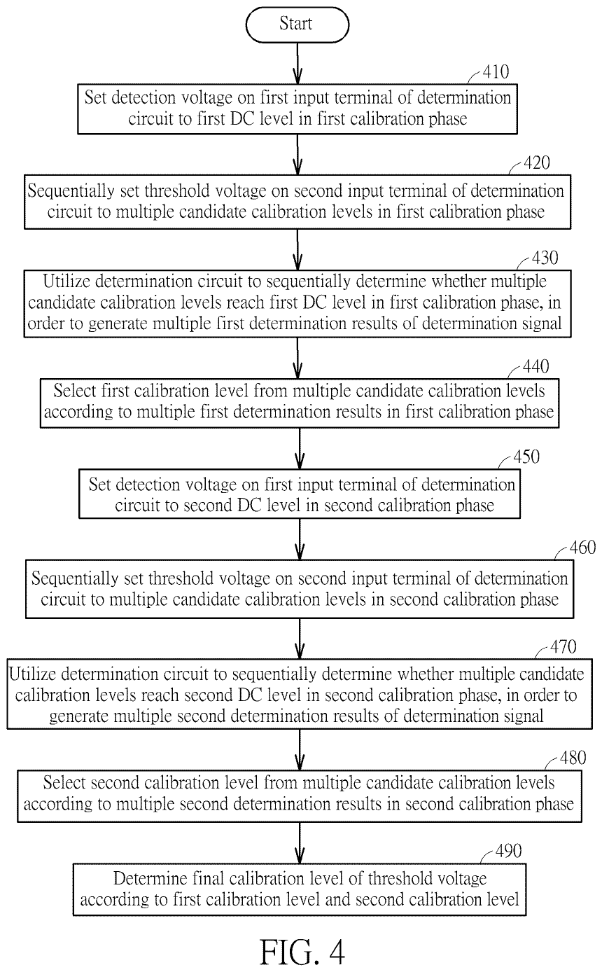

FIG. 4 is a diagram illustrating a working flow of a calibration method of the USB-C connecter chip 220 (e.g. a determination circuit therein such as the determination circuit 222) according to an embodiment of the present invention, where the working flow shown in FIG. 4 may be executed by the USB-C connector chip 220 (e.g, the calibration control circuit 221 therein) shown in FIG. 2. It should be noted that the working flow shown in FIG. 4 is for illustrative purposes only, and is not meant to be a limitation of the present invention. For example, one or more steps may be added, deleted for modified in the working flow shown in FIG. 4. In addition, if the same result can be obtained, these steps do not have to be executed in the exact order shown in FIG. 4.

In Step 410, the USB-C connector chip 220 may set a detection voltage on a first input terminal of the determination circuit such as the determination circuit 222 to a first DC level in a first calibration phase.

In Step 420, the USB-C connector chip 220 may sequentially set a threshold voltage on a second input terminal of the determination circuit such as the determination circuit 222 to multiple candidate calibration levels in the first calibration phase.

In Step 430, the USB-C connector chip 220 may utilize the determination circuit such as the determination circuit 222 to sequentially determine whether the multiple candidate calibration levels reach the first DC level in the first calibration phase, in order to generate multiple first determination results of a determination signal.

In Step 440, the USB-C connector chip 220 may select a first calibration level from the multiple candidate calibration levels according to the multiple first determination results in the first calibration phase.

In Step 450, the USB-C connector chip 220 may set the detection voltage on the first input terminal of the determination circuit such as the determination circuit 222 to a second DC level in a second calibration phase.

In Step 460, the USB-C connector chip 220 may sequentially set the threshold voltage on the second input terminal of the determination circuit such as the determination circuit 222 to the multiple candidate calibration levels in the second calibration phase.

In Step 470, the USB-C connector chip 220 may utilize the determination circuit such as the determination circuit 222 to sequentially determine whether the multiple candidate calibration levels reach the second DC level in the second calibration phase, in order to generate multiple second determination results of the determination signal.

In Step 480, the USB-C connector chip 220 may select a second calibration level from the multiple candidate calibration levels according to the multiple second determination results in the second calibration phase.

In Step 490, the USB-C connector chip 220 may determine a final calibration level of the threshold voltage according to the first calibration level and the second calibration level.

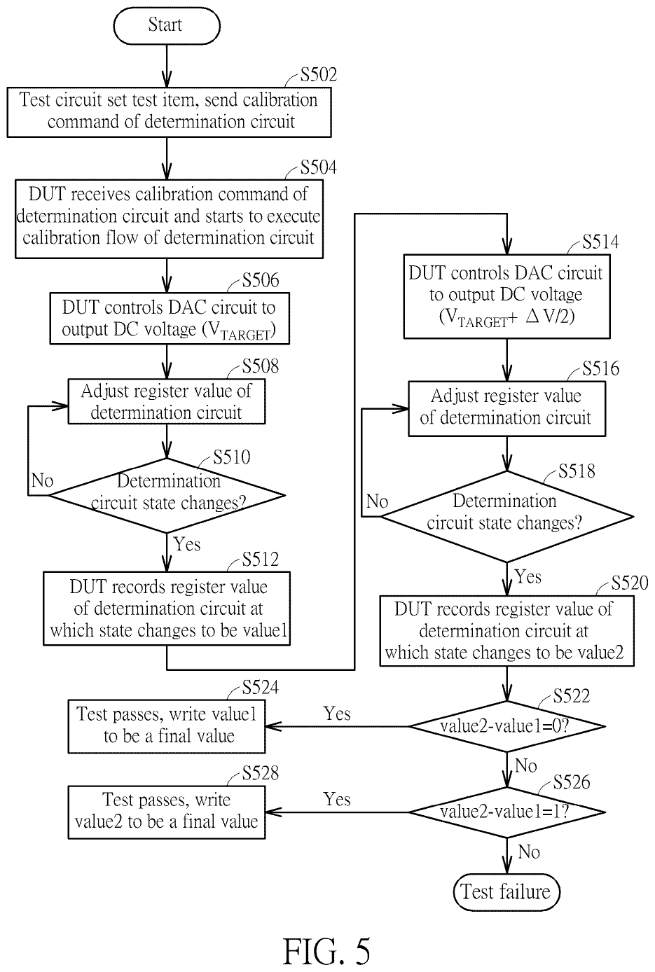

FIG. 5 is a diagram illustrating an example of the calibration method shown in FIG. 4 according to an embodiment of the present invention, where the working flow shown in FIG. 5 may be executed by the test system 10 shown in FIG. 2. It should be noted that the working flow shown in FIG. 5 is for illustrative purposes only, and is not meant to be a limitation of the present invention. For example, one or more steps may be added, deleted for modified in the working flow shown in FIG. 5. In addition, if the same result can be obtained, these steps do not have to be executed in the exact order shown in FIG. 5.

In Step S502, after the test equipment 20 put a DUT such as the USB-C connector chip 220 on the test board 200, the test circuit 210 may set a present test item to be executed to calibration of the determination circuit, and accordingly send a calibration command of the determination circuit to the DUT.

In Step S504, the DUT such as the USB-C connector chip 220 may receive the calibration command of the determination circuit and accordingly start to execute a calibration flow of the determination circuit.

In Step S506, the DUT such as the USB-C connector chip 220 may control the DAC circuit 230 to output a DC voltage, where a voltage level of the DC voltage may be V_{TARGET}.

In Step S508, the DUT such as the USB-C connector chip 220 may adjust a register value of the determination circuit to adjust the calibration level of the threshold voltage V_{TH}.

In Step S510, the DUT such as the USB-C connector chip 220 may determine whether the determination circuit changes its state (e.g. whether the determination signal DCOMP is changed from the logic value “1” to the logic value “0” or changed from the logic value “0” to the logic value “1”). If the determination result shows “Yes”, the working flow proceeds with Step S512. If the determination result shows “No”, the working flow proceeds with Step S508 to adjust the register value of the determination circuit again.

In Step S512, the DUT such as the USB-C connector chip 220 may record the register value of the determination circuit at which the determination circuit changes the state to be value1. For example, when the USB-C connector chip 220 determines that switching the threshold voltage V_{TH} from a specific calibration gear to a next calibration gear makes the determination signal DCOMP be changed from the logic value “1” to the logic value “0” (or changed from the logic value “O” to the logic value “1”) through operations of Steps S508 and S510, the calibration control circuit 221 may record the specific calibration gear to be value1.

In Step S514, the DUT such as the USB-C connector chip 220 may control the DAC circuit 230 to output another DC voltage, where a voltage level of this DC voltage may be (V_{TARGET}+ΔV/2).

In Step S516, the DUT such as the USB-C connector chip 220 may adjust the register value of the determination circuit to adjust the calibration level of the threshold voltage V_{TH}.

In Step S518, the DUT such as the USB-C connector chip 220 may determine whether the determination circuit changes its state (e.g. whether the determination signal DCOMP is changed from the logic value “1” to the logic value “0” or changed from the logic value “0” to the logic value “1”). If the determination result shows “Yes”, the working flow proceeds with Step S520. If the determination result shows “No”, the working flow proceeds with Step S516 to adjust the register value of the determination circuit again.

In Step S520, the DUT such as the USB-C connector chip 220 record the register value of the determination circuit at which the determination circuit changes the state to be value2. For example, when the USB-C connector chip 220 determines that switching the threshold voltage V_{TH} from a specific calibration gear to a next calibration gear makes the determination signal DCOMP be changed from the logic value “1” to the logic value “0” (or changed from the logic value “0” to the logic value “1”) through operations of Steps S516 and S518, the calibration control circuit 221 may record the specific calibration gear to be value2.

In Step S522, the DUT such as the USB-C connector chip 220 may determine whether value1 is equal to value2 (labeled “value2−value1=0?” in FIG. 5 for brevity). If the determination result shows “Yes”, the working flow proceeds with Step S524. If the determination result shows “No”, the working flow proceeds with Step S526.

In Step S524, the test circuit 210 may respond a result of the DUT such as the USB-C connector chip 220 passing the test to the test equipment 20, and the USB-C connector chip 220 may write value1 into a one-time programmable storage device to be a final value of the calibration gear.

In Step S526, the DUT such as the USB-C connector chip 220 may determine whether value2 is a next gear of value1 (labeled “value2−value1=1?” in FIG. 5 for brevity). If the determination result shows “Yes”, the working flow proceeds with Step S528. If the determination result shows “No”, the test circuit 210 may respond a result of a test failure of the DUT such as the USB-C connector chip 220 to the test equipment 20.

In Step S528, the test circuit 210 may respond a result of the DUT such as the USB-C connector chip 220 passing the test to the test equipment 20, and the USB-C connector chip 220 may write value2 into the one-time programmable storage device to be the final value of the calibration gear.

After respective test items of the USB-C connector chip 220 are completed, the test equipment 20 may utilize the robotic arm to remove the USB-C connector chip 220 from the test board 200 and put another DUT on the test board 200 for test and calibration of the next DUT.

In summary, the USB-C connector chip, the test system and the associated calibration method provided by the embodiments of the present invention can obtain two calibration results by inputting two different DC voltages, and decide which calibration result is closer to the target value by determining whether these two calibration results are the same. Furthermore, the embodiments of the present invention will not greatly increase additional costs. Thus, the present invention can solve the problems of the related art without introducing any side effect or in a way that is less likely to introduce side effects.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A universal serial bus type-C (USB-C) connecter chip, comprising:
a determination circuit, configured to determine whether a detection voltage on a first input terminal of the determination circuit reaches a threshold voltage on a second input terminal of the determination circuit, in order to generate a determination signal, wherein the first input terminal is coupled to a detection pin of the USB-C connector chip; and
a calibration control circuit, coupled to the determination circuit, configured to calibrate the threshold voltage transmitted to the second input terminal;
wherein:
in a first calibration phase, the calibration control circuit sets the detection voltage to a first direct current (DC) level, sets the threshold voltage to multiple candidate calibration levels to obtain multiple first determination results of the determination signal, and selects a first calibration level from the multiple candidate calibration levels according to the multiple first determination results;
in a second calibration phase, the calibration control circuit sets the detection voltage to a second DC level, sets the threshold voltage to the multiple candidate calibration levels to obtain multiple second determination results of the determination signal, and selects a second calibration level from the multiple candidate calibration levels according to the multiple second determination results; and
the calibration control circuit determines a final calibration level of the threshold voltage according to the first calibration level and the second calibration level.

2. The USB-C connector chip of claim 1, wherein when the threshold voltage is changed from the first calibration level to a next candidate calibration level of the first calibration level, the determination signal is changed from a first logic value to a second logic value; and when the threshold voltage is changed from the second calibration level to a next candidate calibration level of the second calibration level, the determination signal is changed from the first logic value to the second logic value.

3. The USB-C connector chip of claim 2, wherein a voltage difference between the first DC level and the second DC level is equal to a half of a voltage difference between any two consecutive candidate calibration levels among the multiple candidate calibration levels.

4. The USB-C connector chip of claim 2, wherein when the first calibration level is equal to the second calibration level, the calibration control circuit selects the first calibration level to be the final calibration level.

5. The USB-C connector chip of claim 2, wherein when the second DC level is greater than the first DC level and the second calibration level is greater than the first calibration level, the calibration control circuit selects the second calibration level to be the final calibration level.

6. The USB-C connector chip of claim 2, wherein when the second DC level is less than the first DC level and the second calibration level is less than the first calibration level, the calibration control circuit selects the second calibration level to be the final calibration level.

7. The USB-C connector chip of claim 1, wherein the detection pin is a configuration channel (CC) pin, and multiple different levels of the detection voltage on the CC pin correspond to multiple different connection states of the USB-C connector chip, respectively.

8. The USB-C connector chip of claim 1, wherein the detection pin is a voltage bus (VBUS) pin, and multiple different levels of the detection voltage on the VBUS pin correspond to multiple different power supply states of the USB-C connector chip, respectively.

9. A test system, comprising:
a test circuit, configured to transmit a test command;
a universal serial bus type-C (USB-C) connector chip, coupled to the test circuit, wherein the USB-C connector chip comprises:
a determination circuit, configured to determine whether a detection voltage on a first input terminal of the determination circuit reaches a threshold voltage on a second input terminal of the determination circuit, in order to generate a determination signal, wherein the first input terminal is coupled to a detection pin of the USB-C connector chip; and
a calibration control circuit, coupled to the determination circuit, configured to calibrate the threshold voltage transmitted to the second input terminal according to the test command; and
a digital-to-analog converter (DAC), coupled to the USB-C connector chip, configured to output the detection voltage to the detection pin of the USB-C connector chip;
wherein:
in a first calibration phase, the calibration control circuit controls the DAC to output the detection voltage having a first direct current (DC) level, sets the threshold voltage to multiple candidate calibration levels to obtain multiple first determination results of the determination signal, and selects a first calibration level from the multiple candidate calibration levels according to the multiple first determination results;
in a second calibration phase, the calibration control circuit controls the DAC to output the detection voltage having a second DC level, sets the threshold voltage to the multiple candidate calibration levels to obtain multiple second determination results of the determination signal, and selects a second calibration level from the multiple candidate calibration levels according to the multiple second determination results; and
the calibration control circuit determines a final calibration level of the threshold voltage according to the first calibration level and the second calibration level.

10. The test system of claim 9, wherein when the threshold voltage is changed from the first calibration level to a next candidate calibration level of the first calibration level, the determination signal is changed from a first logic value to a second logic value; and when the threshold voltage is changed from the second calibration level to a next candidate calibration level of the second calibration level, the determination signal is changed from the first logic value to the second logic value.

11. The test system of claim 9, wherein the detection pin is a configuration channel (CC) pin, and multiple different levels of the detection voltage on the CC pin correspond to multiple different connection states of the USB-C connector chip, respectively.

12. The test system of claim 9, wherein the detection pin is a voltage bus (VBUS) pin, and multiple different levels of the detection voltage on the VBUS pin correspond to multiple different power supply states of the USB-C connector chip, respectively.

13. A calibration method of a universal serial bus type-C (USB-C) connecter chip, comprising:
in a first calibration phase, setting a detection voltage on a first input terminal of a determination circuit to a first direct current (DC) level;
in the first calibration phase, setting a threshold voltage on a second input terminal of the determination circuit to multiple candidate calibration levels;
in the first calibration phase, utilizing the determination circuit to determine whether the multiple candidate calibration levels reach the first DC level, in order to generate multiple first determination result of a determination signal;
in the first calibration phase, selecting a first calibration level from the multiple candidate calibration levels according to the multiple first determination results;
in a second calibration phase, setting the detection voltage on the first input terminal of the determination circuit to a second DC level;
in the second calibration phase, setting the threshold voltage on the second input terminal of the determination circuit to the multiple candidate calibration levels;
in the second calibration phase, utilizing the determination circuit to determine whether the multiple candidate calibration levels reach the second DC level, in order to generate multiple second determination result of the determination signal;
in the second calibration phase, selecting a second calibration level from the multiple candidate calibration levels according to the multiple second determination results; and
determining a final calibration level according to the first calibration level and the second calibration level.

14. The calibration method of claim 13, wherein the determination signal is changed from a first logic value to a second logic value in response to the threshold voltage being changed from the first calibration level to a next candidate calibration level of the first calibration level, and the determination signal is changed from the first logic value to the second logic value in response to the threshold voltage being changed from the second calibration level to a next candidate calibration level of the second calibration level.

15. The calibration method of claim 14, wherein a voltage difference between the first DC level and the second DC level is equal to a half of a voltage difference between any two consecutive candidate calibration levels among the multiple candidate calibration levels.

16. The calibration method of claim 14, wherein determining the final calibration level according to the first calibration level and the second calibration level comprises:
in response to the first calibration level being equal to the second calibration level, selecting the first calibration level to be the final calibration level.

17. The calibration method of claim 14, wherein determining the final calibration level according to the first calibration level and the second calibration level comprises:
in response to the second DC level being greater than the first DC level and the second calibration level being greater than the first calibration level, selecting the second calibration level to be the final calibration level.

18. The calibration method of claim 14, wherein determining the final calibration level according to the first calibration level and the second calibration level comprises:
in response to the second DC level being less than the first DC level and the second calibration level being less than the first calibration level, selecting the second calibration level to be the final calibration level.

19. The calibration method of claim 13, wherein the detection pin is a configuration channel (CC) pin, and multiple different levels of the detection voltage on the CC pin correspond to multiple different connection states of the USB-C connector chip, respectively.

20. The calibration method of claim 13, wherein the detection pin is a voltage bus (VBUS) pin, and multiple different levels of the detection voltage on the VBUS pin correspond to multiple different power supply states of the USB-C connector chip, respectively.
